(19) United States
(12) Patent Application Publication
(10) Pub. No.: US 2002/0039845 A1
(43) Pub. Date: Apr. 4, 2002

(54) Exposure apparatus, semiconductor device manufacturing method, exposure apparatus maintenance method and semiconductor manufacturing factory

(76) Inventor: Keiji Yoshimura, Tochigi (JP)

Correspondence Address: FITZPATRICK CELLA HARPER & SCINTO, 30 ROCKEFELLER PLAZA, NEW YORK, NY, 10112, US

(21) Appl. No.: 09/964,648

(22) Filed: Sep. 28, 2001

(30) Foreign Application Priority Data
Oct. 2, 2000 (JP) 2000/302162
Mar. 27, 2001 (JP) 2001/089762

(51) Int. Cl. H01L 21/469

(52) U.S. Cl. 438/784

(57) ABSTRACT

An exposure apparatus that selects an exposure method that matches exposure conditions, from among a plurality of exposure methods includes an exposure method determining unit for switching between exposure methods and determining an exposure method taking into account at least two of a plurality of evaluation item values calculated based on the exposure conditions, and the exposure method determining unit switches among constant speed scanning exposure method, accelerated/decelerated scanning exposure method and static exposure method.

### FIELD OF THE INVENTION

The present invention relates to an exposure apparatus capable of selectively switching between exposure method according to exposure conditions and a method of manufacturing semiconductor devices using the exposure apparatus.

### BACKGROUND OF THE INVENTION

It is generally known that a conventional scanning type exposure apparatus performs exposure after the speeds of a matrix, substrate and light-shielding plate are stabilized.

On the other hand, the Japanese Patent Laid-Open No. 9-223662 specification discloses a scanning type exposure apparatus that performs exposure even when any stage(s) is (are) accelerating or decelerating. On the other hand, there was also a step and repeat type exposure apparatus before scanning exposure (static exposure method).

In the past, different exposure method would be constituted by different exposure apparatuses and used for different purposes. Each exposure method had its own features, and the user would determine the exposure method according to the content to be processed by the exposure apparatus and selectively use the appropriate exposure apparatus. However, in the conventional exposure apparatuses, different exposure methods would be constituted by different machines, those machines would be reused among different processes and the user would determine the exposure method according to the contents to be processed by the exposure apparatus, which would make it difficult to optimize throughput.

On the other hand, the Japanese Patent Laid-Open No. 8-55794 specification discloses a technique that a comparison is made between the size of an effective exposure area of an optical system and the size of an exposure angle of view, if the exposure angle of view is smaller, a step and repeat system is selected and if the exposure angle of view is larger, it is only possible to perform exposure according to a step and scan system and therefore exposure is performed according to the step and scan system.

However, this technique had a problem that it would not be possible to take full advantage of features of the respective exposure methods because it only compared whether it would be possible to print or not based on a comparison between the effective exposure area and exposure angle of view. For example, the step and scan system (hereinafter referred to as “scanning exposure method”) would ignore the advantage of the scanning exposure method of being able to adjust the projection magnification ratio for the scanning direction and non-scanning direction separately.

It is an object of the present invention to provide an exposure apparatus capable of selectively switching between exposure methods, improve the operation of the exposure apparatus through such switching between exposure methods and provide an exposure apparatus capable of optimizing throughput of the exposure apparatus and a method of manufacturing semiconductor devices, etc. using the exposure apparatus.

### SUMMARY OF THE INVENTION

The present invention has been proposed to solve the conventional problems, and has as its object to provide an exposure apparatus capable of executing a plurality of exposure methods and featuring switching means for switching between the plurality of exposure methods. The switching means may also be characterized by the capability of switching between a plurality of exposure methods such as scanning exposure at a constant speed, scanning exposure at a variable speed and static exposure according to different purposes such as increasing productivity, focusing on accuracy or doing maintenance.

The exposure apparatus capable of selectively switching between a plurality of exposure methods according to the preset invention comprises:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means.

The determining means in the above-described exposure apparatus preferably selects from among the plurality of exposure methods taking into account at least two evaluation item values for every wafer, shot or lot.

The calculating means in the above-described exposure apparatus preferably calculates the evaluation item values based on an evaluation item value calculation expression:

C(N):=F(SYL(N))+G(SX(N), SY(N))+H(δX(N), δY(N))+K(L)+P(M)+Q(S, SY(N))

and the exposure conditions set by the above-described setting means.

The calculating means in the above-described exposure apparatus preferably calculates the evaluation item values according to the location of a shot based on the position of the shot in the non-scanning direction (SX) on a substrate and/or the position of the shot in the scanning direction (SY) on the substrate and data.

The calculating means in the above-described exposure apparatus, in the calculation of the evaluation item values, preferably calculates evaluation item values related to a shape shift of a shot base pattern during multiple printing based on an image shift (δX) in the non-scanning direction in the shot and/or image shift (δY) in the scanning direction in the shot.

The calculating means in the above-described exposure apparatus, in the calculation of the evaluation item values, preferably evaluates whether or not to use previously measured correction data based on a shot layout correlation coefficient (L).

The calculating means in the above-described exposure apparatus, in the calculation of the evaluation item values, preferably calculates evaluation item values taking into account at least any one of the shot, substrate and lot printing method indication value (M).

The calculating means in the above-described exposure apparatus, in the calculation of the evaluation item values, preferably calculates evaluation item values to synchronize the drive stages taking into account a synchronization accuracy target value (S).

The plurality of exposure methods in the above-described exposure apparatus preferably include three exposure methods of static exposure that performs exposure with the stage standing still, constant speed scanning exposure with the stage running at a constant speed while carrying out scanning exposure and accelerated/decelerated scanning exposure with the stage running at an inconstant speed while carrying out scanning exposure, and

the determining means selects an exposure method that matches the exposure conditions from among the three exposure methods based on the evaluation item values.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

in which the calculating means, in the calculation of the evaluation item values, calculates evaluation item values according to the location of a shot based on the position of the shot in the non-scanning direction on a substrate and/or the position of the shot in the scanning direction on the substrate and data, and

the determining means selects an exposure method that matches the location of the shot according to the calculated evaluation item values.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

wherein the calculating means, in the calculation of the evaluation item values, calculates evaluation item values related to a shape shift of a shot base pattern during multiple printing based on an image shift in the non-scanning direction in the shot and/or image shift in the scanning direction in the shot,

the determining means selects an exposure method that matches conditions of the shape shift of a shot base pattern according to the calculated evaluation item values during the multiple printing.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

wherein the calculating means, in the calculation of the evaluation item values, evaluates whether or not to use previously measured correction data based on a shot layout correlation coefficient, and

the determining means selects an exposure method according to the evaluation as to whether or not to use the evaluated previously measured correction data.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

in which the calculating means, in the calculation of the evaluation item values, calculates evaluation item values taking into account at least any one of the shot, substrate and lot printing method indication values, and

the determining means selects an exposure method that matches the specified printing method based on the calculated evaluation item values.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

in which the calculating means, in the calculation of the evaluation item values, calculates evaluation item values to synchronize the drive stages taking into account a synchronization accuracy target value, and

the determining means selects an exposure method that matches the synchronization of the drive stage based on the calculated evaluation item values.

Furthermore, the exposure apparatus capable of selectively switching between a plurality of exposure methods according to the present invention includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means,

in which the determining means selects based on the calculated evaluation item values one appropriate exposure method from among three exposure methods of static exposure that performs exposure with the stage standing still, constant speed scanning exposure with the stage running at a constant speed while carrying out scanning exposure and accelerated/decelerated scanning exposure with the stage running at an inconstant speed while carrying out scanning exposure.

The determining means of the above-described exposure apparatus preferably selects from among at least two exposure methods of constant speed scanning exposure with the stage running at a constant speed while carrying out scanning exposure and accelerated/decelerated scanning exposure with the stage running at an inconstant speed while carrying out scanning exposure.

The determining means of the above-described exposure apparatus preferably further selects static exposure that performs exposure with the stage standing still.

The calculating means of the above-described exposure apparatus preferably calculates the evaluation item values based on the exposure conditions for every lot, substrate and shot and the determining means switches between exposure methods according to the evaluation item values.

The semiconductor device manufacturing method according to the present invention includes the steps of:

installing a plurality of semiconductor manufacturing apparatuses for a plurality of processes including an exposure apparatus in a factory; and

manufacturing semiconductor devices through a plurality of processes using the plurality of semiconductor manufacturing apparatuses,

in which the exposure apparatus comprises:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means.

The above-described semiconductor device manufacturing method preferably includes the steps of:

connecting the plurality of semiconductor manufacturing apparatuses via a local area network;

connecting the local area network and an external network outside the factory;

acquiring information on the exposure apparatus from a database on the external network using the local area network and the external network; and

controlling the exposure apparatus based on the acquired information.

The semiconductor manufacturing factory according to the present invention includes:

a plurality of semiconductor manufacturing apparatuses including an exposure apparatus;

a local area network that connects the plurality of semiconductor manufacturing apparatuses; and

a gateway that connects the local area network and an external network outside the semiconductor manufacturing factory,

in which the exposure apparatus includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means.

Furthermore, the maintenance method for an exposure apparatus according to the present invention includes the steps of:

preparing a database for storing information on the maintenance of the exposure apparatus on an external network outside the factory in which the exposure apparatus is installed;

connecting the exposure apparatus to the local area network in the factory; and

performing maintenance of the exposure apparatus based on information stored in the database using the external network and the local area network,

in which the exposure apparatus includes:

setting means for setting exposure conditions for an exposure target;

calculating means for calculating evaluation item values to determine an exposure method based on the set exposure conditions; and

determining means for selecting an exposure method that matches the exposure conditions for the exposure target based on the evaluation item values calculated by the calculating means.

The above-described maintenance method for an exposure apparatus preferably includes the steps of:

the vendor or user of the exposure apparatus providing a maintenance database connected to an external network outside the factory;

allowing access to the maintenance database from the semiconductor manufacturing factory via the external network; and

sending the maintenance information stored in the maintenance database to the semiconductor manufacturing factory via the external network.

The above-described exposure apparatus preferably further includes:

an interface for connecting a network;

a computer for executing network software that performs data communication of the maintenance information of the exposure apparatus via the network; and

a display for displaying the maintenance information of the exposure apparatus communicated by the network software executed by the computer.

The network software of the above-described exposure apparatus preferably provides on the display a user interface for accessing maintenance database provided by the vendor or user of the exposure apparatus connected to an external network of the factory in which the exposure apparatus is installed and allows information to be acquired from the database via the external network.

When a manual mode exposure method is specified as the exposure conditions, the determining means of the above-described exposure apparatus preferably selects the specified exposure method independently of the evaluation item values, and

when an auto mode exposure method is specified as the exposure conditions, the above-described determining means selects an exposure method that matches the exposure conditions according to the evaluation item values.

When it is impossible to realize the exposure method due to the exposure conditions, the determining means of the above-described exposure apparatus preferably registers a value exceeding threshold data for selecting the exposure method as an offset value in the calculated evaluation item values or registers a value for reducing this threshold value as an offset value and determines a feasible exposure method.

Further objects, features and advantages of the present invention, will become apparent from the following detailed description of embodiments of the present invention with reference to the accompanying drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic view showing a configuration of an exposure apparatus according to an embodiment of the present invention;

FIG. 2 is a perspective view showing exposure light intensity profile according to a scanning exposure method of the exposure apparatus according to the embodiment of the present invention;

FIG. 3 is a view illustrating a method of determining evaluation item values to determine an exposure method in the exposure apparatus according to the embodiment of the present invention;

FIG. 4 is a top view illustrating merits and demerits of a focus system with respect to a difference in the exposure method of the exposure apparatus according to the embodiment of the present invention;

FIG. 5A and 5B are views illustrating a method of processing an exception that occurs in determining an exposure method of the exposure apparatus according to the embodiment of the present invention;

FIG. 6 is a flow chart illustrating processing of the exposure apparatus to which the system according to the present invention is applied;

FIG. 7 is a flow chart illustrating processing in determining an exposure method of the exposure apparatus according to the embodiment of the present invention;

FIG. 8A and 8B are flow charts illustrating preprocessing in determining an exposure method of the exposure apparatus according to the embodiment of the present invention;

FIG. 9 is a conceptual diagram of a production system of semiconductor devices using the exposure apparatus according to the present invention viewed from a certain angle;

FIG. 10 is a conceptual diagram of the production system of semiconductor devices using the exposure apparatus according to the present invention viewed from another angle;

FIG. 11 illustrates a specific example of a user interface;

FIG. 12 is a view illustrating a flow of a device manufacturing process; and

FIG. 13 is a view illustrating a wafer process.

### DETAILED DESCRIPTION OF THE PREFERRED EMBODIMENTS

Preferred embodiments of the present invention will now be described in detail in accordance with the accompanying drawings.

An embodiment of the present invention provides a hybrid exposure apparatus that selects from among a plurality of exposure methods a system that matches exposure conditions and applies the system. Once each exposure method is selected, this hybrid exposure apparatus can select shot information, parameters and a correction sequence required for the exposure method as appropriate and perform exposure.

The exposure apparatus that selectively switches between exposure methods can be implemented in the following apparatus configuration. A scanning type exposure apparatus comprises a control section that executes a plurality of stage driving methods and an exposure method determining section that calculates evaluation item values based on exposure conditions, determines an exposure method based on the determination result and determines parameters, a sequence and correction system necessary for the exposure method.

Processing contents of the exposure method determining section and the control section will be explained. There are two methods of switching between exposure methods; one method that the user explicitly switches between exposure methods taking into account the processing purpose and the other method that the exposure apparatus automatically determines an exposure method.

As the case where the exposure apparatus automatically determines an exposure method, it is possible to conceive a case where the angles of view of shots formed on a substrate, array mode, execution content and required accuracy are input to the exposure apparatus. It is also possible to conceive a system whereby the required accuracy is directly determined from a recipe which is given on line. For example, it is possible to switch between a scanning exposure method and static exposure method.

When an exposure with a small angle of view is performed, a step and repeat system has an advantage over a step and scan system in that it is not necessary to accelerate or decelerate the stage, thus improving throughput.

Therefore, the size of the shot angle of view can serve as criteria in determining, for example, scanning exposure and static exposure. When switching is performed, a threshold etc. is provided for the exposure apparatus so as to optimize throughput.

Furthermore, when an exposure is performed onto a wafer with a base, it is possible to conceive a method whereby the amount of false recognition by the base pattern of the focus sensor is measured before starting the exposure, measurement reproducibility is measured to determine which of the static exposure focus and scanning exposure focus is to be used to optimize the accuracy and productivity of the exposure apparatus.

Furthermore, one of the features of the scanning type exposure apparatus is an advantage of being able to set a magnification ratio for the scanning direction and non-scanning direction separately. For this reason, when a magnification difference between directions after measuring the printing shape of the base shot is large, scanning exposure is selected and static exposure is selected otherwise to improve the focus accuracy and throughput. It is also possible for a control system selection determining section to determine switching between these exposure methods.

Furthermore, while the static exposure method may fail to obtain a focus point around a wafer, the scanning exposure method allows sensor measuring points to be moved, making it possible to perform exposure onto parts closer to the exposure area. Thus, it is possible to improve the focus accuracy by selecting an exposure method. Furthermore, it is also possible to simply classify types of exposure to be executed from now into categories such as maintenance and production and switch between the control systems based on this setting.

Moreover, in the case of scanning exposure, if the accuracy of wafer printing (CD, overlay, etc.) is reduced, it may be difficult to determine which of the accuracy of the lens or accuracy of stage performance has been reduced. Therefore, static exposure according to a step and repeat system is performed and the stage factor and lens factor of the wafer printing accuracy are separated.

Next, in the case of scanning exposure, it is also possible to switch between two types of cases, carrying out an exposure while running the stage at a constant speed and carrying out an exposure while accelerating or decelerating the stage. As the maximum scanning speed increases, it is necessary to increase stage acceleration and jerk in order to reduce the increase of the stage stroke.

Although it depends on the performance of the stage, there is concern that increasing the acceleration of the stage may deteriorate the accuracy of synchronization between stages. Thus, in a process whose required accuracy is high, it is effective to adopt a system of carrying out an exposure during acceleration or deceleration. Thinking in this way, it is possible to switch between two ways of exposure methods; exposure giving priority to throughput in the case of exposure at a constant speed and exposure focused on accuracy during acceleration or deceleration and it is desirable to select and determine from two types of alternatives, exposure at a constant speed or exposure during acceleration or deceleration.

Furthermore, it is also possible to switch between two scanning exposure methods according to the accuracy of synchronization required for the relevant process. At this time, it is also possible to select from among the two exposure methods based on an abstract concept such as a recipe.

After determining switching between the static and scanning exposures systems, and switching between the two types of scanning exposure methods, the exposure method determining section determines the correction method, sequence, etc. required for the respective exposure methods.

For example, consider the two types of exposure methods; static exposure method and scanning exposure method. The static exposure method differs from the scanning exposure method in the positions of focus measuring points, exposure amount control system, magnification ratio correcting means and drive tables used when the stage is driven.

Furthermore, consider two types of exposure methods; exposure at a constant speed and exposure during acceleration or deceleration. The amount of false recognition of pattern at focus measuring points and tilt (amount of one-sided nebulosity) due to a difference in the amount of acceleration/deceleration and the method of adjusting illumination, etc. vary depending on the speed.

The exposure control system determining section has the functions of automatically determining the difference between static and scanning exposure methods or difference between scanning exposure at a constant speed and exposure during acceleration or deceleration and automatically invoking these correction items and sequences separately. Furthermore, the differences between exposure methods are conventionally handled through operations of the exposure apparatus, but if an exposure method can be set manually, that is enough. Furthermore, it is also possible to store in a memory the correspondence of various correction sequences (measurement etc. required before carrying out exposure processing) necessary for the respective exposure methods and consider the respective processing times and improvement of accuracy, or consider correction values to be diverted from the exposure methods of the previous wafer or lot, etc. and use these factors to determine the exposure method.

Provided with such functions, it is possible to constitute an exposure apparatus capable of automatically switching between exposure methods according to the purpose, accuracy and productivity.

Furthermore, the present invention is also applicable to a semiconductor device manufacturing method comprising a step of installing in a semiconductor manufacturing factory a manufacturing apparatus group for various processes including any one of the above-described exposure apparatuses and a step of manufacturing semiconductor devices through a plurality of processes using the manufacturing apparatus group. The semiconductor device manufacturing method may further comprise a step of connecting between apparatuses of the manufacturing apparatus group via a local area network and a step of communicating information on at least one apparatus in the manufacturing apparatus group between the local area network and an external network outside the semiconductor manufacturing factory. It is also possible to obtain maintenance information of the manufacturing apparatus through data communication by accessing a database provided by the vendor or user of the exposure apparatus via the external network or perform production control through data communication with a semiconductor manufacturing factory other than the above-described semiconductor manufacturing factory via the external network. Especially, as a feature of the exposure apparatus according to this system, it is possible to acquire information on the lot or wafer process distortion (magnification ratio, distortion) or information on dust or wafer flatness from the production control host via a network and use the information for switching between exposure methods.

Furthermore, the present invention is also applicable to a semiconductor manufacturing factory comprising a manufacturing apparatus group for various processes including any one of the above-described exposure apparatuses, a local area network that connects between apparatuses of the manufacturing apparatus group and a gateway that enables access from the local area network to an external network outside the factory, making possible data communication of information on at least one of apparatuses in the manufacturing apparatus group.

Furthermore, the present invention is also applicable to a maintenance method for any one of the above-described exposure apparatuses comprising a step of the vendor or user of the exposure apparatus providing a maintenance database connected to the external network of the semiconductor manufacturing factory, a step of allowing access from the semiconductor manufacturing factory to the maintenance database via the external network and a step of sending maintenance information stored in the maintenance database to the semiconductor manufacturing factory via the external network.

Furthermore, any one of the exposure apparatuses of the present invention preferably further comprises a display, a network interface and a computer to execute network software to allow data communication of maintenance information of the exposure apparatus via a computer network, and the network software preferably provides a user interface on the display to access the maintenance database provided by the vendor or user of the exposure apparatus connected to the external network of the factory in which the exposure apparatus is installed, making it possible to acquire information from the database via the external network.

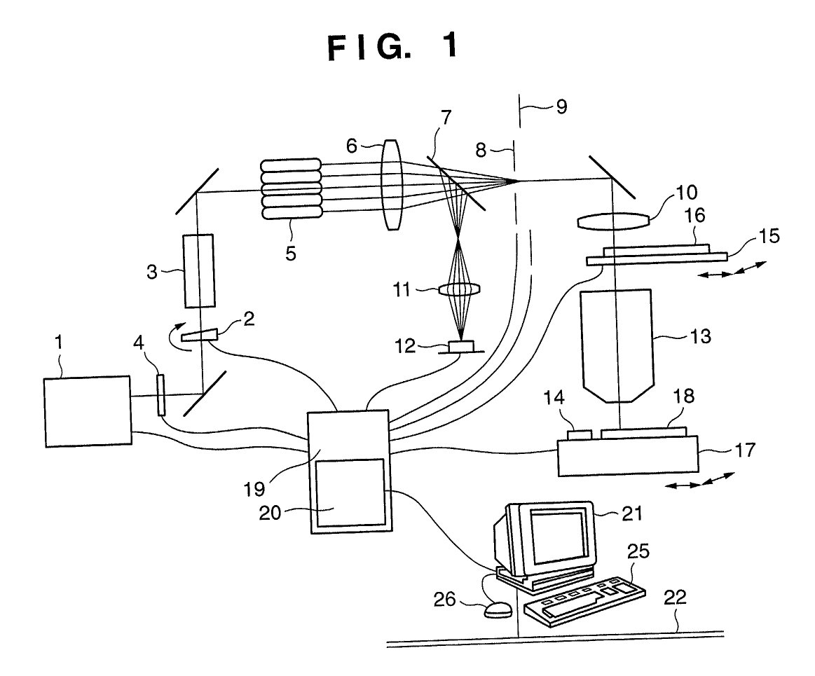

Based on the attached drawings, the exposure apparatuses of embodiments of the present invention will be explained below. FIG. 1 is a view illustrating an outlined configuration of an exposure apparatus of an embodiment of the present invention. In FIG. 1, reference numeral 1 denotes a light source and can be, for example, an excimer laser or i-ray lamp. Reference numeral 4 denotes a beam attenuating filter with a plurality of attenuation ratios to attenuate the light beam from the light source 1 and is an optical member represented by an ND filter with different transmittances. Reference numeral 2 denotes an optical unit for eliminating illumination irregularities by vibrating the angle of coherent light such as a laser beam; 3, a beam shaping optical system for shaping the light beam from the light source 1 and making it coherent; 5, an optical integrator; 6, a condensing lens for illuminating the surface of a masking blade 9 with the light flux from the optical integrator 5 which is a secondary light source.

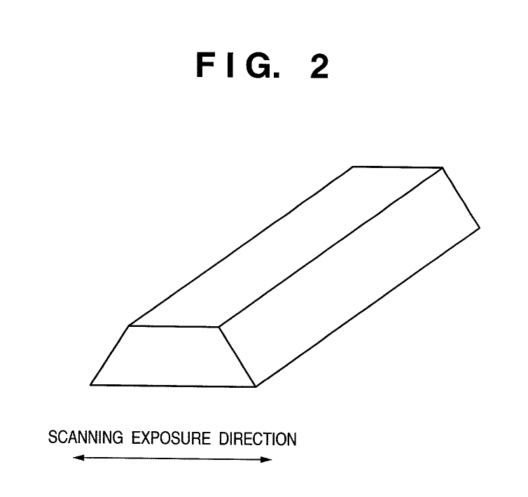

Reference numeral 7 denotes a half-mirror, splits part of the light flux from the optical integrator 5 and the split light flux is introduced to a photo-detector 12 through a condensing lens 11 and used to detect the amount of exposure when an exposure is performed onto a wafer 18 as a substrate. The masking blade 9 consists of four upper/lower and right/left independently operating light shielding plates and exists on an optical conjugate plane with a reticule 16 as the original plate with respect to an image formation lens 10. An exposure slit 8 consists of two sets of light shielding plates whose shape shields the light flux in the direction perpendicular to the optical axis on the plane of this sheet. Furthermore, since the exposure slit 8 is in a position shifted from the surface of the masking blade 9 in the optical axis direction, a light intensity distribution by the exposure slit 8 has a trapezoidal distribution as shown in FIG. 2. FIG. 2 is a three-dimensional schematic view illustrating the light intensity distribution on the exposed surface.

The image formation lens 10 introduces the light shielded by the masking to form an image on the reticule 16. A projection lens 13 projects the image formed by the reticule 16 onto the wafer 18. The reticule 16 is positioned and placed on a reticule stage 15. The wafer 18 is placed on a wafer stage 17. These stages are driven in a floating state by means of an air pat etc. and can be driven two-dimensionally freely.

The amount of exposure given to the surface of the wafer 18 is detected and controlled by the photo-detector 12. An illuminometer 14 is attached to the surface of the wafer 18 and a desired amount of exposure is given to the surface of the wafer 18 by checking a relationship with the photo-detector 12 before starting an exposure.

An exposure apparatus interface (I/F) 21 specifies the operation of the exposure apparatus through its input devices (keyboard 25 and mouse 26, etc.). At the same time, the exposure apparatus I/F 21 controls wafer printing conditions, printing layout, etc. allowing the operator to use the exposure apparatus by selecting conditions to be used from among the conditions under control. Furthermore, the exposure apparatus I/F 21 may be connected to a trunk network in an environment in which the exposure apparatus is installed or to a local network 22, etc. and operating conditions, etc. of the exposure apparatus may be downloaded from there.

A main control section 19 executes various correction functions of the exposure apparatus, drives and controls the units according to the instructions of the operator given to the exposure apparatus I/F 21 or instructions downloaded from the trunk network 22.

One of the features of the exposure apparatus according to this embodiment is an exposure method determining section 20. The exposure method determining section 20 selects an exposure method based on data such as the exposure conditions received by the main control section 19. The exposure method determining section 20 determines an evaluation item value for every item necessary to determine an exposure method. This exposure method is determined according to a composite value of an evaluation item value for every shot, an evaluation item value for every wafer and an evaluation item value for every lot.

The evaluation content for every shot may include a shot size (angle of view), printing location on the surface of a wafer, situation of shot distortion, etc. The evaluation item value for every lot may include a layout shape in the preceding lot or layer, scan speed, etc. About these evaluation items, evaluation item values in each shot of the lot loaded at that time are calculated. Those evaluation item values determine the exposure method.

The method of calculating evaluation item values is as follows:

C(N):=F(SYL(N))+G(SX(N), SY(N))+H(δX(N), δY(N))+K(L)+P(M)+Q(S, SY(N)) (Equation 1)

In Equation 1, the names of the variables have the following meanings:

SYL: Size of the shot in the scanning direction

SX: Position of the shot on the wafer surface in the non-scanning direction

SY: Position of the shot on the wafer surface in the scanning direction

δX: Image shift in the non-scanning direction in the shot

δY: Image shift in the scanning direction in the shot

L: Layout correlation coefficient

M: Lot printing method indication value

N: Shot number (index) on one wafer

S: Synchronization accuracy target value

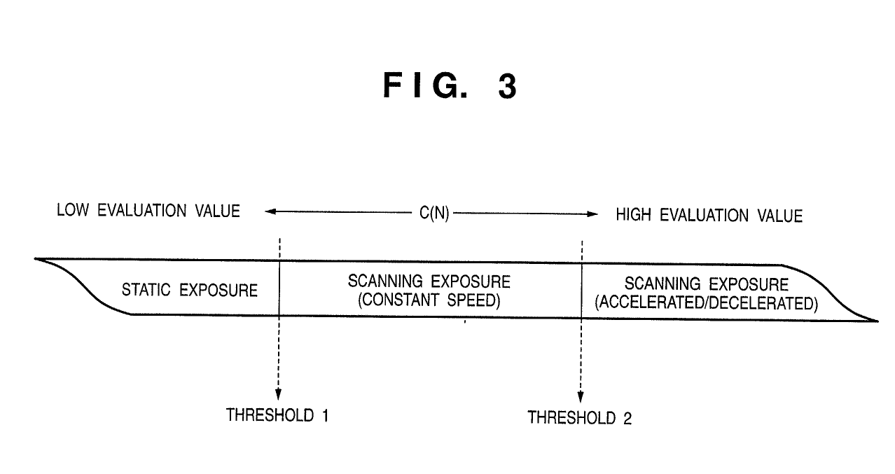

C(N) in Equation 1 indicates the evaluation item value of the (N-shot)th exposure method on the wafer, provides a threshold for the value and determines which system is used to perform an exposure for every shot; scanning exposure (constant speed), scanning exposure (accelerated/decelerated) or static exposure. Basically, it is possible to determine the exposure method using a one-dimensional index as shown in FIG. 3.

FIG. 3 shows that as the evaluation item value calculated by Equation 1 increases in the + direction, it is desirable to adopt scanning exposure as the exposure method of the shot. On the contrary, it is possible to determine that as the evaluation item value calculated by Equation 1 increases in the− direction, it is more advantageous to adopt a static exposure method as the exposure method of the shot. As shown in FIG. 3, an evaluation item value is calculated and a threshold is provided for the value and finally the exposure method of the shot is determined based on the value.

The term of the function F in Equation 1 indicates an item related to the shot size. As the shot size reduces, acceleration/deceleration control of the stage increases with respect to the exposure scanning area (length), and therefore the static exposure method becomes more advantageous. Therefore, the evaluation item value according to the shot size is, for example, as shown below:

F(SYL):=FA×SYL+FB(where SYL≦SLW: exposure light width) (Equation 2)

where, FA and FB are constants and predetermined values. (Equation 2) is effective when SYL is smaller than exposure light width SLW. There may also be cases where the value of (Equation 2) will increase exponentially.

The term of the function G in Equation 1 is a term related to the location of a shot and gives an evaluation of the exposure method. There may be cases where it is necessary to change the shot location according to the feature of the focus detection method of the exposure apparatus or change the focus method according to the feature corresponding to the location. Thus, the term G reflects influences of these cases. Alternatively, this term of the function G reflects the case where the situation of shot distortion of the base layer has location dependency.

In the focusing according to the scanning exposure method, it is a general practice that the focus at each position is measured during a scan and the focusing is performed according to this value. For this reason, it is necessary to perform focus measurement in real time while the wafer is moving, which generally results in low performance of tracking irregularities on the wafer surface (dust, fouling on the chuck, etc.). On the other hand, since it is possible to perform focus measurement at any position during a scan, satisfactory focus measurement is attained even in areas such as the perimeter of a wafer where focus measurement is applicable to only a limited area. Therefore, more specifically, the G term reflects influences in the following case.

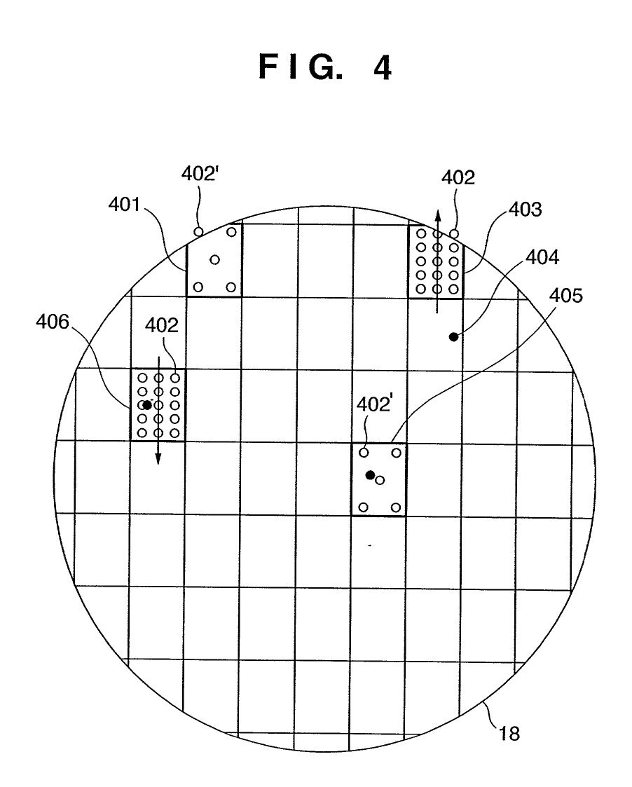

FIG. 4 will be explained. FIG. 4 shows that exposure shot layouts (rectangular areas in FIG. 4) are formed on the surface of the wafer 18 (circle in FIG. 4) and exposure is performed according to these layouts. Reference numeral 402 shows the position at which a focus sensor performs measurement (focus measuring position). A shot 401 is a shot where static exposure is performed around the perimeter of the wafer 18, while a shot 403 is a shot where scanning exposure is performed around the perimeter of the wafer 18.

Static exposure performs exposure to shots all together and if some measuring points are outside the wafer as in the case of the shot 401, the remaining four measured values are used to perform exposure to the entire shot. In contrast, in the case of the shot 403, exposure is performed simultaneously with a scan and move, and therefore only the focus measuring point at the shot edge receives influences of being outside the wafer. Therefore, the scanning exposure method guarantees the focus accuracy as far as the measuring points are included in the shot 403 without going beyond the perimeter of the wafer. That is, the G term reflects influences of focus measuring points according to such shot locations.

Furthermore, reference numeral 404 denotes dust stuck to the surface of the wafer 18. In the case of shots 405 and 406 to which dust is stuck, it is seen that the shot 405 is subjected to static exposure while the shot 406 is subjected to scanning exposure. Since fewer focus measuring points are located in the shot 405, the probability of measuring dust is low, preventing the entire shot 405 from being defocused unnecessarily. In contrast, the shot 406 is under scanning exposure and there are more focus measuring points in the shot than during static exposure. Thus, there is a higher probability in the case of the shot 406 that dust will also be measured and more areas will be defocused than the shot 405. Similarly, information on irregularities on the surface of the chuck on which a wafer is placed is stored in memory etc. and these irregularities may be treated in the same way as in the case of dust. In addition, it is also possible to acquire information on wafer irregularities to be processed from a network and reflect the information in the G term. That is, the G term reflects influences of information on wafer irregularities due to dust or chuck irregularities.

The H term in Equation 1 is a term related to a shape shift of the base pattern of the relevant shot when multiple printing is performed. A significant difference between the scanning exposure method and static exposure method in the alignment performance is that the scanning exposure method allows a magnification ratio of a shot (primary, tertiary component, etc.) to be corrected in the scanning direction and non-scanning direction. Thus, it is possible to switch between exposure methods according to positional differences between the scanning and non-scanning directions. For example, the following evaluation expression is conceivable:

H(δX(N), δY(N)):=HA×|δX(N)−δY(N)|+HB (Equation 3)

where, HA and HB are constants and predetermined.

The term of the K function in Equation 1 is a term generated when the previously measured correction data is diverted. When the same base or process exists in the exposure apparatus or on-line host, etc., the correction data of the lot may be diverted, which makes it possible to improve throughput. For example, the area subject to focus measurement varies in a shot between two exposure methods; the scanning exposure method and static exposure method.

The focus measuring points 402 in reference numerals 403 and 406 in FIG. 4 show focus measuring points according to the scanning exposure method, while the focus measuring points 402′ in reference numerals 401 and 405 show focus measuring points according to the static exposure method. Since the amount of false recognition is included in the amount of measurement under the influence of the base layer during focus measurement, the base pattern is measured before exposure, the amount of false recognition is measured and the amount of focus measurement is corrected. The base pattern varies depending on the location, but when both the base pattern and the relevant wafer shot layout are the same, focus measurement may be omitted. Moreover, measuring conditions etc. during measurement when alignment is performed can also be basically diverted as long as both the base pattern and layout are the same. However, wafer factors and resist application conditions may vary depending on the lot, and therefore the substitution of a focus measured value of the previous lot becomes a trade-off between throughput and accuracy. Thus, for example, the term of the function K is expressed by the following expression:

K(L):=KA×L (Equation 4)

where, KA is a constant and a predetermined value.

“L” here refers to a shot layout correlation coefficient and L is a coefficient which becomes 0 when the shot coordinates of a layout are shifted or the base pattern or layout is wrong, and becomes 1 when all items are identical.

The term of the function P in Equation 1 indicates the method of printing the lot and when the lot is to be printed by limiting it to either of the exposure methods, the indication of the printing method is reflected in evaluation item values through this item. Inclusion in the evaluation item values prevents the user from specifying the printing method erroneously.

P(M)=PA|M:=specification of static exposure method

PB|M:=specification of scanning exposure method (Equation 5)

Here, PA and PB are constants and predetermined values.

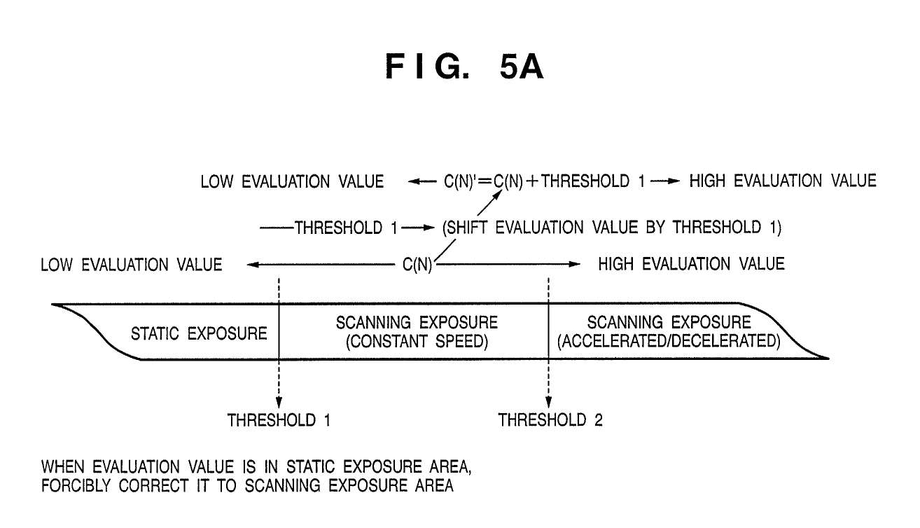

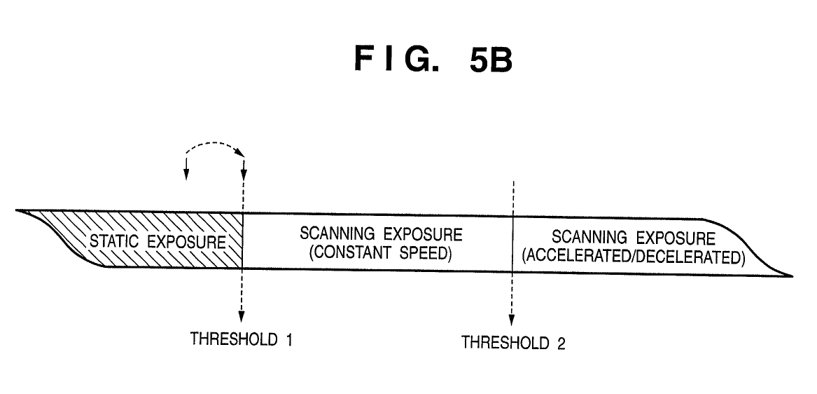

If, for example, SLW in Equation 2 is greater than a default value, impossibility of exposure by either exposure method may be determined by an exposure layout or recipe. For example, when shot width in the scanning direction SYL is greater than exposure light with SLW, batch exposure is not possible in the static exposure method, and therefore either one of the two exposure methods is used. In this case, various methods may be used such as preventing the evaluation item value from falling below a threshold 1 by adding the threshold 1 to the evaluation item value as shown in FIG. 5A, or totally applying scanning exposure (at a constant speed) when an evaluation item value smaller than the threshold 1 is calculated as shown in FIG. 5B. Moreover, instead of providing the P term, the threshold may also be changed.

When stage synchronization accuracy is specified, the Q term in Equation 1 is the term corresponding thereto. The synchronization accuracy of each drive stage of a scanning type exposure apparatus generally deteriorates as the acceleration of the stage increases. That is, static exposure or scanning type exposure method (accelerated/decelerated) is advantageous under the setting with strict synchronization accuracy, whereas it has demerits such as limitation of the exposure area and reduction of throughput, etc. Therefore, the term Q of synchronization accuracy may be set as follows:

Q(S, SY(N)): KA

where,

SY(N)≦SLW, S≦SR : KB

where,

SY(N)>SLW, S≦SR : KC for other than above (Equation 6)

In Equation 6 above, S denotes a synchronization accuracy target value, SR denotes a synchronization accuracy required value, and when S is smaller than this value, the requirement for synchronization accuracy is high and it is necessary to apply exposure according to the static exposure method (KA is added to the evaluation item value) or accelerated/decelerated scanning exposure method (KB is added to the evaluation item value). In other cases, evaluation item values are basically calculated without considering this item.

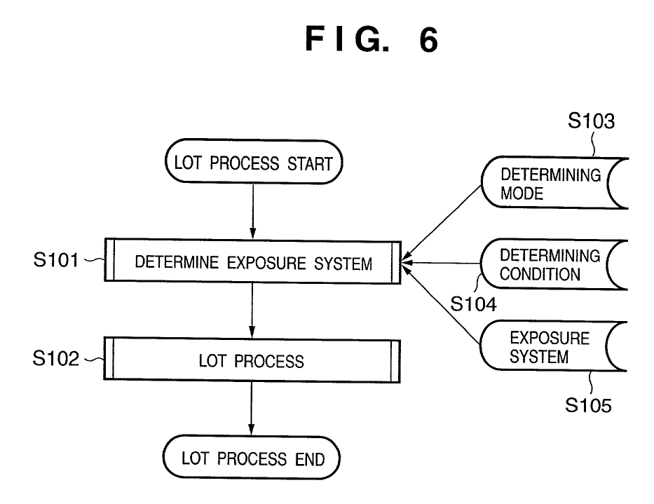

Then, processing of the exposure apparatus according to this embodiment will be shown in FIG. 6. Once a lot process is started, exposure method determining step S101 is executed by an exposure condition determining section 20 where any one of static, scanning (at a constant speed) or scanning (accelerated/decelerated) exposure methods is determined. In determining the exposure method, the determining mode process, determining condition data, etc. in steps S103 to S105 are referenced. The exposure method determining mode (S103) is a processing step of determining whether the exposure method is determined automatically (by the exposure apparatus) or manually (according to user specification). The user himself/herself determines this and can input this processing step to the exposure apparatus I/F 21 using the keyboard 25 etc. beforehand. Furthermore, the setting of the determining condition data (S104) is a step of setting data concerning various kinds of required accuracy such as alignment accuracy of the lot to be processed, focus accuracy, exposure accuracy and the determination of the exposure method including wafer shape data such as the lot layout and base pattern condition. Exposure method (S105) is a step of setting data by exposure method used when the determination result in the determining mode S103 is manual and three values of static, scanning (at a constant speed) and scanning (accelerated/decelerated) are set. This is a step of determining an optimal exposure method for the lot to be processed using these two data groups. After the exposure method is determined, lot processing step S102 processes the lot according to the determined exposure method and terminates the lot processing.

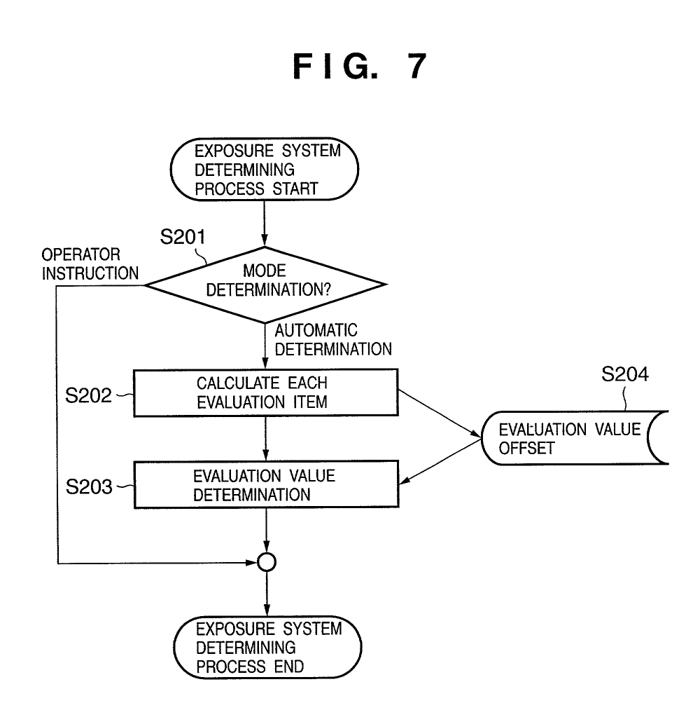

Next, a detailed flow of exposures system determining step S101 will be shown in FIG. 7. Once the exposures system determining processing starts, the process moves on to determining mode determining step S201 first. Here, if the mode is set in such a way that the user forcibly specifies the exposure method and exposure is performed according to that system, the exposures system determining process is terminated without calculating evaluation item values. If an automatic determining (the exposure apparatus-determined) mode is selected in determining mode determining step S201, the process of each evaluation item calculating step S202 is performed. Here, values corresponding to above-described Equations 1 to 6 are calculated. If a few exposure methods cannot be executed due to exposure conditions etc. at this time, evaluation item value offset data is registered (S204). More specifically, as described above, if batch exposure is not possible according to a static exposure method, for example, when shot width in the scanning direction SYL is greater than exposure light width SLW according to an exposure layout or recipe, such a value that will make the evaluation item value exceed a scanning exposure threshold in all cases by adding a value exceeding threshold data to the evaluation item value obtained through a calculation is registered as an offset value, or contrarily a value that will reduce this threshold is registered as an offset value. Then, the evaluation item value is determined using Equation 1 (S203) and it is determined which of the exposure methods the evaluation item value matches. The value of the evaluation item value offset data registered at this time (S204) is acted on the evaluation item value or threshold to make a correct evaluation and determination. Alternatively, as described above, when batch exposure according to the static exposure method is not possible, it is also possible to forcibly perform exposure according to the scanning exposure (at a constant speed) system. In this case, an instruction for performing exposure according to the scanning exposure (at a constant speed) system itself acts as an offset.

On the contrary, when synchronous scanning, scanning exposure control or scanning focus measurement, etc. cannot be performed because exposure apparatus adjustment etc. is not ready, if an automatic determining mode is selected, it is also possible to register as an offset value a value that will make the evaluation item value fall below a scanning exposure threshold in all cases by subtracting it from the evaluation item value, or contrarily register as an offset value a value that will increase this threshold and determine the evaluation item value using Equation 1 or forcibly perform exposure according to the static exposure method.

There are cases where an exposure angle of view of a wafer to be processed may vary from one shot to another. For example, a TEG (Test Element Group: pattern for a chip test) etc. is placed between exposure shots and processed in the same process. In this case, the exposure angle of view varies a great deal from one shot to another, and therefore determining an exposure method for every shot can provide more accurate exposure for each shot without averaging evaluation item values and also improve throughput of the wafer. Thus, the present invention can also determine an exposure method for every shot or wafer. As the processing content in such a case, it is possible to group shots taking into account exposure conditions (angle of view, synchronization accuracy, etc.) for each shot beforehand, by determining exposure methods for all shots of the wafer and performing processing according to the exposure method common to most shots, etc., and calculate the value in Equation 1 for each group.

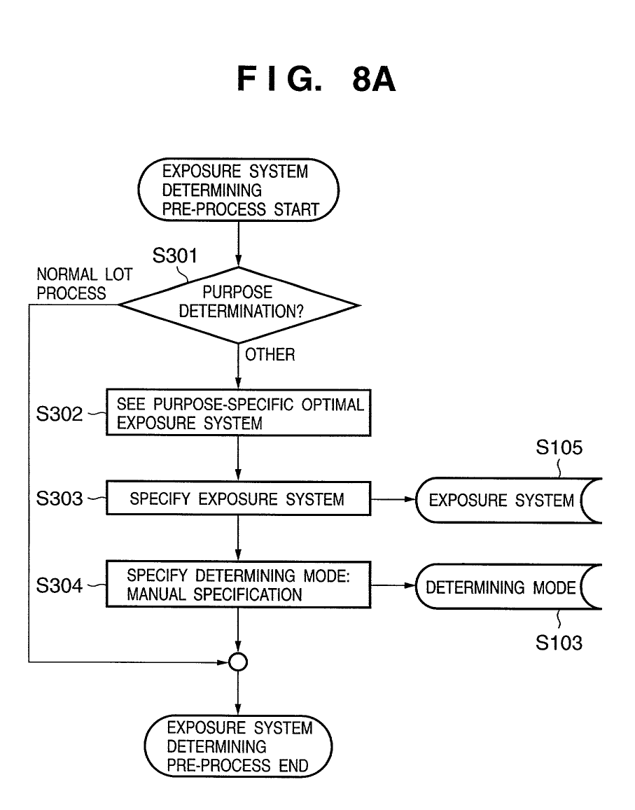

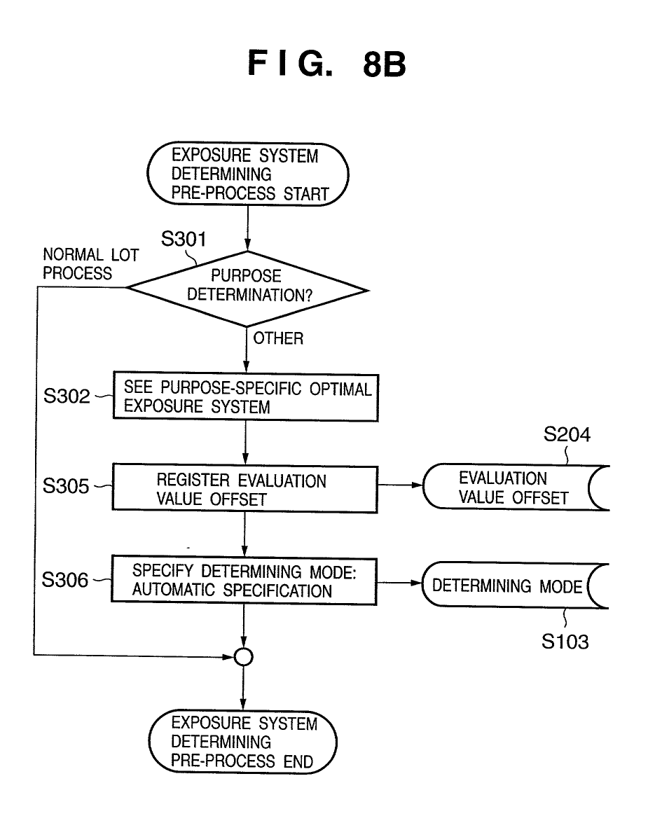

This system can also be used for when the exposure apparatus is used for purposes other than a normal purpose such as maintenance. Two specific processing flows as the exposure method determining pre-processing will be shown in FIG. 8A and FIG. 8B. The flow chart shown in FIG. 8A is a method of directly changing a determining mode. The purpose when the exposure apparatus is driven is determined in step S301 and a purpose-specific optimal exposure method is referenced in step S302. Determination according to a purpose specific optimal exposure method is a process of registering an optimal exposure method according to the purpose beforehand and determining an optimal system from among the registered systems and an optimal exposure method is determined when a purpose is given. In step S303, the optimal exposure method obtained is registered in exposure method-specific data (S105) and the determining mode (S103) is specified as “manual” by specification of the exposure method determining mode in step S304. Furthermore, the flow shown in FIG. 8B applies to the system whereby evaluation item values are shifted. The process up to step S302 is the same process as that of the flow shown in FIG. 8A and by evaluation item value offset registration in step S305, an evaluation item value offset is registered (S204). By determining mode specification in step S306, a determining mode is automatically specified (S103). Either of these two exposure method determining pre-processes allows an exposure method that matches the processing purpose to be determined.

The user I/F of the exposure apparatus according to this embodiment may include input items such as specifications of exposure purpose, exposure method and determining mode, etc. and output items such as an exposure method according to which lots are currently being processed. Both or either of these input and output items may be displayed at the exposure apparatus to assist the operator in operations. Even if the input item is hidden in the lot processing recipe, the exposure apparatus according to the present invention can be still constituted. Furthermore, the output item may also be referenced on line etc.

Providing the above-described contents, the exposure apparatus according to this embodiment has the effects of being able to select an optimal exposure method, operate an optimal apparatus according to the purpose and optimize throughput easily. (Embodiment of semiconductor production system)

Then, an example of a semiconductor device (semiconductor chips such as IC and LSI, LCD panel, CCD, thin-film magnetic head, micromachines, etc.) production system using the exposure apparatus according to the present invention will be explained. This is a system that performs maintenance services such as handling of trouble of the manufacturing apparatus installed in a semiconductor manufacturing factory, periodic maintenance and supply of software, etc. using a computer network outside the manufacturing factory.

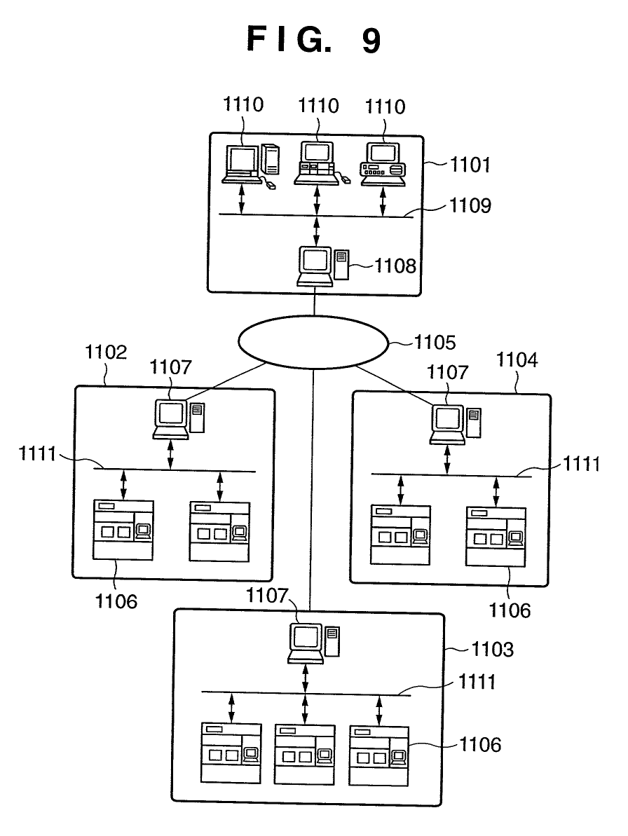

FIG. 9 is a view of the overall system extracted from a certain angle. In FIG. 9, reference numeral 1101 denotes the office of the vendor (apparatus supplier) who supplies a semiconductor device manufacturing apparatus. Actual examples of the manufacturing apparatus include a semiconductor manufacturing apparatus for various processes used in a semiconductor manufacturing factory, for example, pre-processing equipment (lithography apparatus such as exposure apparatus, resist processor, etching apparatus, and thermal processor, film formation apparatus, flattening apparatus, etc.) and post-processing equipment (assembly apparatus, inspection apparatus, etc.). The office 1101 is equipped with a host control system 1108 that supplies a maintenance database for the manufacturing apparatus, a plurality of operation terminal computers 1110 and a local area network (LAN) 1109 constructed by connecting these computers to construct an intranet etc. The host control system 1108 is equipped with a gateway to connect the LAN 1109 to the Internet 1105 which is a network outside the office and a security function to restrict accesses from the outside.

On the other hand, reference numerals 1102 to 1104 denote manufacturing factories of semiconductor manufacturers who are the users of the manufacturing apparatuses. Manufacturing factories 1102 to 1104 may be factories belonging to manufacturers different from each other or may be factories belonging to the same manufacturer (for example, a pre-processing factory and post-processing factory, etc.). The factories 1102 to 1104 are each equipped with a plurality of manufacturing apparatuses 1106, a local area network (LAN) 1111 that connects these apparatuses to construct an intranet etc. and a host control system 1107 as a monitoring apparatus for monitoring the operating situation of each manufacturing apparatus 1106. The host control system 1107 provided for each factory 1102 to 1104 is equipped with a gateway to connect the LAN 1111 in each factory to the Internet 1105 which is a network outside the factory. This allows the users from the LAN 1111 in each factory to access the host control system 1108 on the vendor 1101 side via the Internet 1105 and allows only the users restricted by the security function of the host control system 1108 to access. More specifically, it is possible to notify status information indicating the operating situation of each manufacturing apparatus 1106 (for example, situation of a manufacturing apparatus in which trouble occurs) from the factory to the vendor via the Internet 1105 or receive information of a response to the notification (for example, information indicating a troubleshooting method, troubleshooting software or data), maintenance information such as latest software and help information, etc. from the vendor. For data communications between each factory 1102 to 1104 and the vendor 1101 and for data communications between LANs 1111 of the respective factories, a communication protocol (TCP/IP) generally used over the Internet is used. Instead of using the Internet as the external network outside the factories, it is also possible to use a dedicated network (ISDN etc.) with high security preventing a third party's access. Furthermore, the host control system is not limited to the one supplied by the vendor, but the user can also construct a database, place it on an external network and allow a plurality of the user's factories to access the relevant database. Here, data such as the aforementioned evaluation item value or determining mode used to deduce it, determination conditions, exposure method is sent to the vendor as the status information indicating the operating situation of the exposure apparatus, and the host control system 1108 on the vendor side or any of the operation terminal computers 1110 connected thereto processes this statistically and sends software or help information that matches the operating situation of each exposure apparatus to the host control system 1107 on the factory side. On the other hand, the exposure apparatus side can also receive values such as process distortion (magnification ratio, distortion) etc. of lots and wafers currently being processed, dust, irregularities on the wafer surface, etc. from the vendor side or the control system on the user side and use this information for switching between exposure methods.

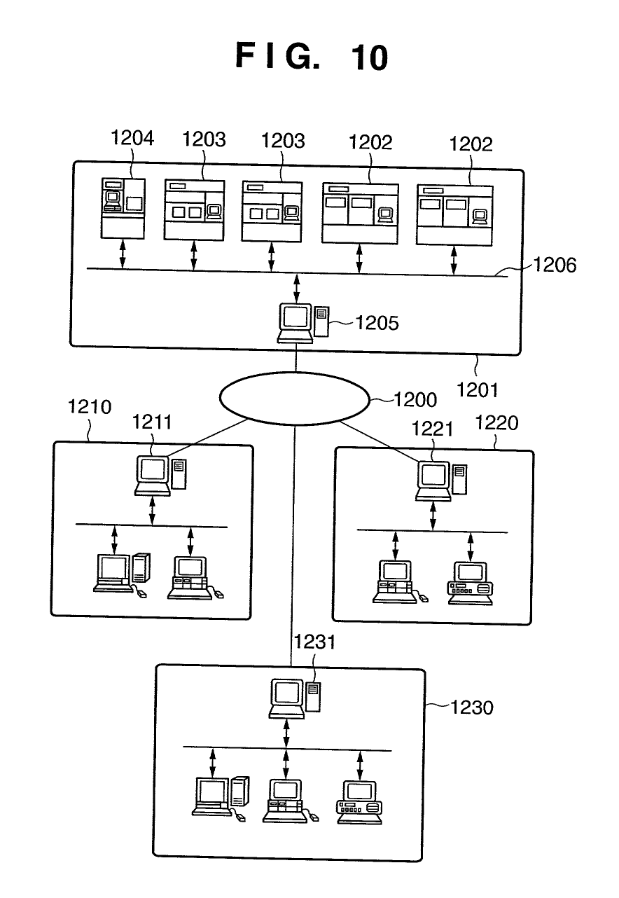

Here, FIG. 10 is a conceptual diagram of the overall system of this embodiment extracted from an angle different from that in FIG. 9. The foregoing example describes the case where a plurality of user factories each equipped with a manufacturing apparatus and the control system of the vendor of the manufacturing apparatus are connected via an external network and production control of each factory and data communication of information of at least one manufacturing apparatus are carried out via the external network. In contrast, this example describes a case where a factory equipped with manufacturing apparatuses of a plurality of vendors, the plurality of manufacturing apparatuses and the control systems of the respective vendors are connected via an external network outside the factory and maintenance information of each manufacturing apparatus is communicated with each other. In FIG. 10, reference numeral 1201 denotes a manufacturing factory of the manufacturing apparatus user (semiconductor device manufacturer) and the manufacturing line of the factory introduces manufacturing apparatuses for carrying out various processes, here for example, an exposure apparatus 1202, a resist processor 1203 and a film formation processor 1204. FIG. 10 describes only one manufacturing factory 1201, but a plurality of factories are actually connected via a network in a similar way. The respective apparatuses in the factory are connected via a LAN 1206 to form an intranet and the host control system 1205 controls movements of the manufacturing line.

On the other hand, offices of vendors (apparatus suppliers) such as an exposure apparatus manufacturer 1210, a resist processor manufacturer 1220 and a film formation apparatus manufacturer 1230 are each equipped with host control systems 1211, 1221 and 1231 for carrying out remote maintenance of the supplied apparatuses and these systems are each equipped with a maintenance database and a gateway which is an external network as described above. The host control system 1205 that controls the apparatuses in the user manufacturing factory and the vendor control systems 1211, 1221 and 1231 for the respective apparatuses are connected via the Internet which is an external network 1200 or a dedicated network. If trouble occurs in any one of the apparatuses on this manufacturing line in this system, the manufacturing line ceases to operate, but by receiving remote maintenance from the vendor of the apparatus in trouble via the Internet 1200, it is possible to speedily cope with the trouble and suppress the interruption of the manufacturing line to a minimum.

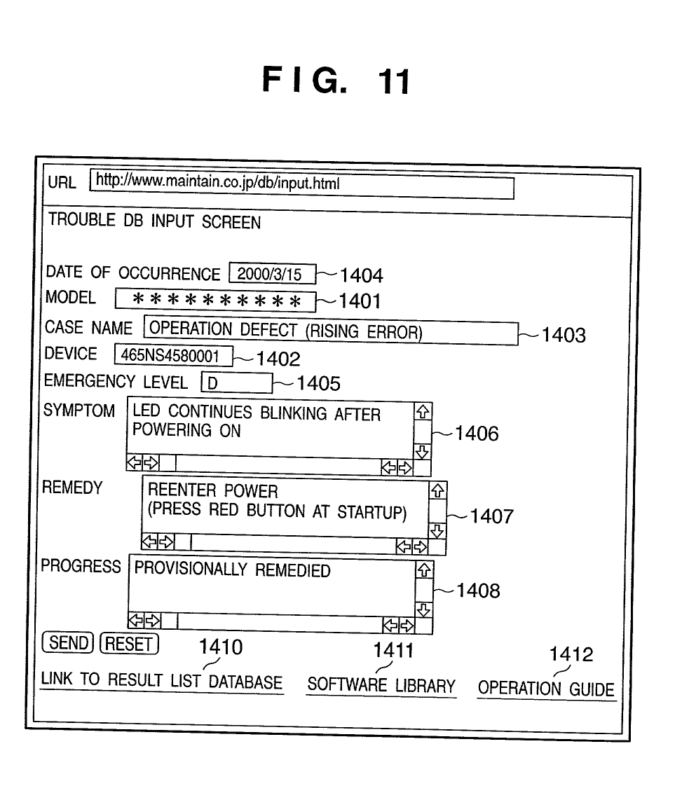

The manufacturing apparatuses installed in the semiconductor manufacturing factory are each equipped with a display, a network interface, and a computer that executes network access software stored in a storage device and software for operation of the apparatus. As the storage device, a built-in memory, hard disk or network file server, etc. is available. The above-described network access software includes a dedicated or general-purpose web browser and provides on a display a user interface with a screen whose example is shown in FIG. 11. The operator who controls the manufacturing apparatus in each factory enters, while referencing the screen information such as the model 1401 of the manufacturing apparatus, serial number 1402, case name of trouble 1403, date of occurrence 1404, emergency level 1405, symptom 1406, remedy 1407, progress 1408, etc. in input items on the screen. The information entered is sent to a maintenance database via the Internet and the resulting appropriate maintenance information is replied from the maintenance database and shown on the display. Furthermore, the user interface provided by the web browser further provides hyper link functions 1410 to 1412 as shown in the figure, allowing the operator to access further detailed information of each item, extract software of the latest version to be used for the manufacturing apparatus from a software library provided by the vendor or extract an operation guide (help information) to be used as reference for the factory operator. Here, the maintenance information provided from the maintenance database also includes information on the above-described present invention and the above-described software library also provides the latest software to implement the present invention. That is, as one piece of status information indicating the operating situation of the corresponding exposure apparatus, data such as the aforementioned evaluation item values or determining mode used to deduce the evaluation item values, determining condition and exposure method is sent to the corresponding vendor of the exposure apparatus, and the host control system on the vendor side or any operation terminal computer connected thereto processes this data statistically and sends software or help information that matches the operating situation of each exposure apparatus to the host control system 1205 on the factory side. The host control system 1205 transfers the relevant information only to the corresponding exposure apparatus.

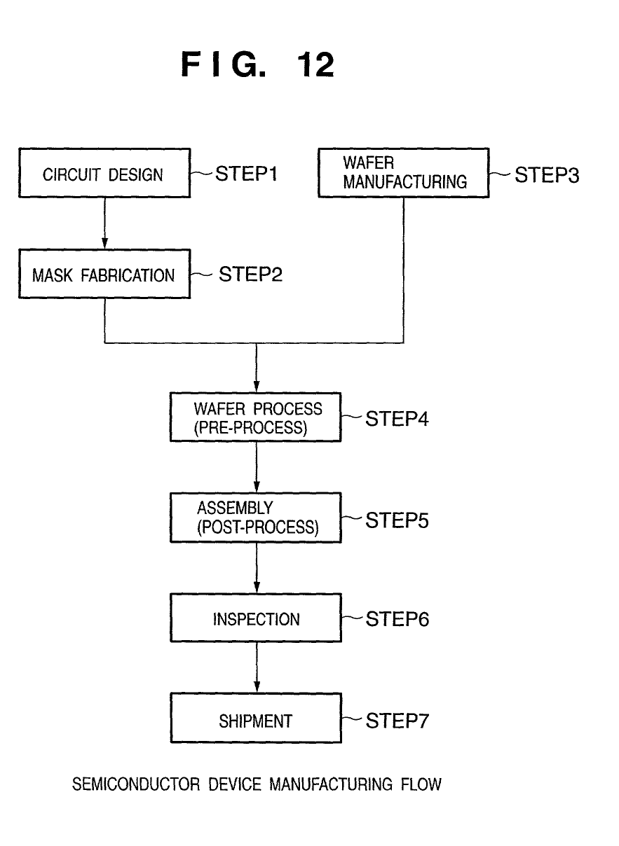

Then, the manufacturing process of the semiconductor devices using the above-described production system will be explained. FIG. 12 shows a flow of an overall manufacturing process of semiconductor devices. In step S1 (circuit design), a circuit design for a semiconductor device is carried out. In step S2 (mask fabrication), a mask on which the designed circuit pattern is formed is fabricated. On the other hand, in step S3 (wafer manufacturing), a wafer is manufactured using a material such as silicon. Step S4 (wafer process) is called a “pre-process” in which an actual circuit is formed on the wafer using the mask and wafer prepared above using a lithography technology. The next step S5 (assembly) is called a “post-process” and is a step in which a semiconductor chip is created using the wafer manufactured in step S4 and includes assembly processes such as an assembly process (dicing, bonding), packaging process (chip sealing), etc. In step S6 (inspection), the semiconductor device manufactured in step S5 is subjected to an operation check test and resistance test, etc. The semiconductor device is completed through these processes and shipped (step S7). The pre-process and post-process are carried out at different dedicated factories and maintenance is performed using the above-described remote-controlled maintenance systems at the respective factories. Between the pre-process factory and post-process factory, information for production control and maintenance of the apparatuses is communicated with each other via the Internet or a dedicated network.

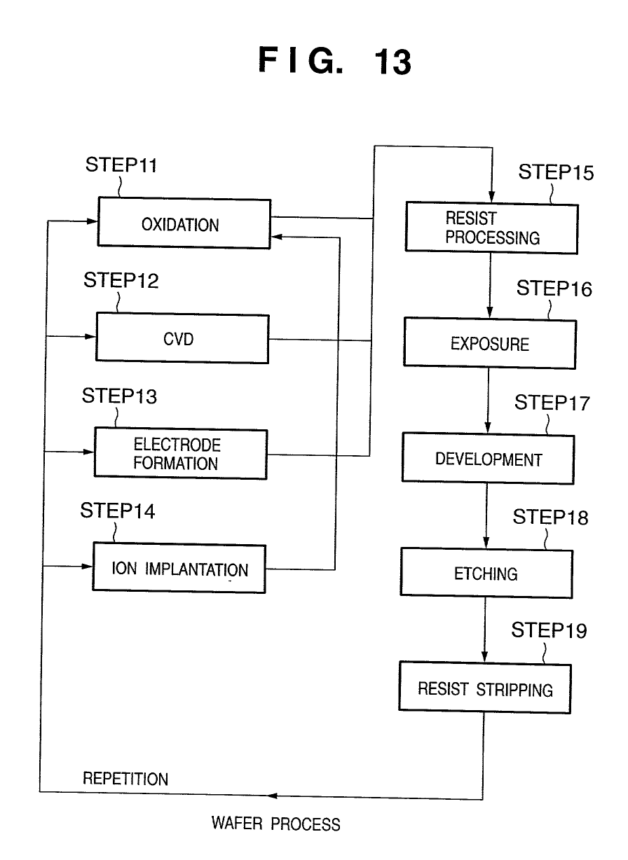

FIG. 13 shows a detailed flow of the above-described wafer process. In step S11 (oxidation), the surface of a wafer is oxidized. In step S12 (CVD), an insulation film is formed on the surface of the wafer. In step S13 (formation of electrodes), electrodes are formed on the wafer by means of vapor deposition. In step S14 (ion implantation), ions are implanted into the wafer. In step S15 (resist processing), a photosensitive material is applied to the wafer. In step S16 (exposure), the above-described exposure apparatus prints the mask circuit pattern onto the wafer and performs exposure. In step S17 (development), the exposed wafer is developed. In step S18 (etching), the part other than the developed resist image is chipped off. In step S19 (resist stripping), the unnecessary resist after the etching is removed. By repeating these steps, multiple circuit patterns are formed on the wafer. The manufacturing apparatus used for each process is subjected to maintenance using the above-described remote-controlled maintenance system, which prevents trouble or even if trouble occurs it is possible to speedily recover the original condition, thus improving productivity of semiconductor devices compared to the conventional systems.

As many apparently widely different embodiments of the present invention can be made without departing from the spirit and scope thereof, it is to be understood that the invention is not limited to the specific embodiments thereof except as defined in the claims.

What is claimed is:

1. An exposure apparatus capable of selectively switching between a plurality of exposure methods, comprising:
setting means for setting exposure conditions for an exposure target;
a calculating means for calculating evaluation item values to determine the exposure method based on said set exposure conditions; and
determining means for selecting an exposure method that matches the exposure conditions for said exposure target based on the evaluation item values calculated by said calculating means.

2. The exposure apparatus according to claim 1, wherein said determining means selects from among said plurality of exposure methods taking into account at least two evaluation item values for every wafer, shot or lot.

3. The exposure apparatus according to claim 1, wherein said calculating means calculates said evaluation item values based on an evaluation item value calculation expression:
C(N):=F(SYL(N))+G(SX(N), SY(N))+H(δX(N), δY(N))+K(L)+P(M)+Q(S, SY(N))
where
SX: Position of the shot on the wafer in the nonscanning direction
SY: Position of the shot on the wafer in the scanning direction
δX: Image shift in the non-scanning direction in the shot
δY: Image shift in the scanning direction in the shot
L: Layout correlation coefficient
M: Lot printing method indication value
N: Shot number on one wafer
S: Synchronization accuracy target value and the exposure conditions set by said setting means.

4. The exposure apparatus according to claim 1, wherein said calculating means, in the calculation of said evaluation item values, calculates evaluation item values according to the location of a shot based on the position of the shot in the non-scanning direction (SX) on a substrate and/or the position of the shot in the scanning direction (SY) on the substrate and data.

5. The exposure apparatus according to claim 1, wherein said calculating means, in the calculation of said evaluation item values, calculates evaluation item values related to a shape shift of a shot base pattern during multiple printing based on an image shift (δX) in the non-scanning direction in the shot and/or image shift (δY) in the scanning direction in the shot.

6. The exposure apparatus according to claim 1, wherein said calculating means, in the calculation of said evaluation item values, evaluates whether or not to use previously measured correction data based on a shot layout correlation coefficient (L).

7. The exposure apparatus according to claim 1, wherein said calculating means, in the calculation of said evaluation item values, calculates evaluation item values taking into account at least any one of the shot, substrate and lot printing method indication value (M).

8. The exposure apparatus according to claim 1, wherein said calculating means, in the calculation of said evaluation item values, calculates evaluation item values to synchronize the drive stages taking into account a synchronization accuracy target value (S).

9. The exposure apparatus according to claim 1, wherein the plurality of exposure methods include three exposure methods of static exposure that performs exposure with the stage standing still, constant speed scanning exposure with the stage running at a constant speed while carrying out scanning exposure and accelerated/decelerated scanning exposure with the stage running at an inconstant speed while carrying out scanning exposure, and
said determining means selects an exposure method that matches the exposure conditions from among the three exposure methods based on said evaluation item values.

10. An exposure apparatus capable of selectively switching between a plurality of exposure methods, comprising:
setting means for setting exposure conditions for an exposure target;
a calculating means for calculating evaluation item values to determine an exposure method based on the set exposure conditions; and
determining means for selecting an exposure method that matches the exposure conditions for said exposure target based on the evaluation item values calculated by said calculating means,
wherein said calculating means, in the calculation of said evaluation item values, calculates evaluation item values according to the location of a shot based on the position of the shot in the non-scanning direction on a substrate and/or the position of the shot in the scanning direction on the substrate and data, and
said determining means selects an exposure method that matches the location of said shot according to said calculated evaluation item values.

11. An exposure apparatus capable of selectively switching between a plurality of exposure methods, comprising:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means,
wherein said calculating means, in the calculation of said evaluation item values, calculates evaluation item values related to a shape shift of a shot base pattern during multiple printing based on an image shift in the non-scanning direction in the shot and/or image shift in the scanning direction in the shot,
said determining means selects an exposure method that matches conditions of the shape shift of a shot base pattern according to said calculated evaluation item values during the multiple printing.

12. An exposure apparatus capable of selectively switching between a plurality of exposure methods, comprising:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means,
wherein said calculating means, in the calculation of said evaluation item values, evaluates whether or not to use previously measured correction data based on a shot layout correlation coefficient, and
said determining means selects an exposure method according to the evaluation as to whether or not to use said evaluated previously measured correction data.

13. An exposure apparatus capable of selectively switching between a plurality of exposure methods, comprising:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means,
wherein said calculating means, in the calculation of said evaluation item values, calculates evaluation item values taking into account at least any one of the shot, substrate or lot printing method indication value, and
said determining means selects an exposure method that matches the specified printing method based on said calculated evaluation item values.

14. An exposure apparatus capable of selectively switching between a plurality of exposure methods, comprising:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means,
wherein said calculating means, in the calculation of said evaluation item values, calculates evaluation item values to synchronize the drive stages taking into account a synchronization accuracy target value, and
said determining means selects an exposure method that matches the synchronization of the drive stage based on said calculated evaluation item values.

15. An exposure apparatus capable of selectively switching between a plurality of exposure methods, comprising:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means,
wherein said determining means selects based on said calculated evaluation item values one appropriate exposure method from among three exposure methods of static exposure that performs exposure with the stage standing still, constant speed scanning exposure with the stage running at a constant speed while carrying out scanning exposure and accelerated/decelerated scanning exposure with the stage running at an inconstant speed while carrying out scanning exposure.

16. The exposure apparatus according to claim 15, wherein said determining means selects from among at least two exposure methods of constant speed scanning exposure with the stage running at a constant speed while carrying out scanning exposure and accelerated/decelerated scanning exposure with the stage running at an inconstant speed while carrying out scanning exposure.

17. The exposure apparatus according to claim 15, wherein said determining means selects static exposure that performs exposure with the stage standing still.

18. The exposure apparatus according to claim 15, wherein said calculating means calculates the evaluation item values based on the exposure conditions for every lot, substrate and shot and said determining means switches between exposure methods according to said evaluation item values.

19. A semiconductor device manufacturing method, comprising the steps of:
installing a plurality of semiconductor manufacturing apparatuses for a plurality of processes including an exposure apparatus in factory; and
manufacturing semiconductor devices through a plurality of processes using said plurality of semiconductor manufacturing apparatuses,
wherein the exposure apparatus (claim 1) comprises:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means.

20. The semiconductor device manufacturing method according to claim 19, further comprising the steps of:
connecting said plurality of semiconductor manufacturing apparatuses via a local area network;
connecting said local area network and an external network outside said factory;
acquiring information on said exposure apparatus from a database on said external network using said local area network and said external network; and
controlling said exposure apparatus based on said acquired information.

21. A semiconductor manufacturing factory, comprising:
a plurality of semiconductor manufacturing apparatuses including an exposure apparatus;
a local area network that connects said plurality of semiconductor manufacturing apparatuses; and
a gateway that connects said local area network and an external network outside said semiconductor manufacturing factory,
wherein said exposure apparatus (claim 1) comprises:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means.

22. A maintenance method for an exposure apparatus, comprising the steps of:
preparing a database for storing information on the maintenance of said exposure apparatus on an external network outside a factory in which the exposure apparatus is installed;
connecting said exposure apparatus to a local area network in said factory; and
performing maintenance of said exposure apparatus based on information stored in said database using said external network and said local area network,
wherein said exposure apparatus (claim 1) comprises:
setting means for setting exposure conditions for an exposure target;
a calculating means for calculating evaluation item values to determine an exposure method based on said set exposure conditions; and
determining means for selecting an exposure method that matches the exposure conditions for said exposure target based on the evaluation item values calculated by said calculating means.

23. The maintenance method for an exposure apparatus according to claim 22, comprising the steps of:
a vendor or user of said exposure apparatus providing a maintenance database connected to the external network outside the factory;
allowing access to said maintenance database from said semiconductor manufacturing factory via said external network; and
sending the maintenance information stored in said maintenance database to the semiconductor manufacturing factory via said external network.

24. The exposure apparatus according to claim 1, comprising:
an interface for connecting a network;
a computer for executing network software that performs data communication of the maintenance information of said exposure apparatus via said network; and
a display for displaying the maintenance information of said exposure apparatus communicated by the network software executed by said computer.

25. The exposure apparatus according to claim 24,
wherein said network software provides on said display a user interface for accessing the maintenance database provided by the vendor or user of said exposure apparatus connected to the external network of the factory in which said exposure apparatus is installed and allows information to be acquired from said database via said external network.

26. The exposure apparatus according to claim 1,
wherein when a manual mode exposure method is specified as said exposure conditions, said determining means selects the specified exposure method independently of said evaluation item values, and
when an auto mode exposure method is specified as said exposure conditions, said determining means selects an exposure method that matches the exposure conditions according to said evaluation item values.

27. The exposure apparatus according to claim 1,
wherein when it is impossible to realize the exposure method due to the exposure conditions, said determining means registers a value exceeding threshold data for selecting said exposure method as an offset value in the calculated evaluation item values or registers a value for reducing this threshold as an offset value and determines a feasible exposure method.
